(19) United States
(12) Patent Application Publication
(10) Pub. No.: US 2026/0051884 A1
(43) Pub. Date: Feb. 19, 2026

(54) TRANSIENT DETECTION FOR CONTROLLING INTERNAL BIAS BUFFER

(71) Applicant: MEDIATEK INC., Hsinchu City (TW)

(72) Inventors: Hsin-Cheng Hsu, Hsinchu City (TW); Yu-Shen Lin, Hsinchu City (TW)

(73) Assignee: MEDIATEK INC., Hsinchu City (TW)

(21) Appl. No.: 19/300,684

(22) Filed: Aug. 15, 2025

Related U.S. Application Data
(60) Provisional application No. 63/684,537, filed on Aug. 19, 2024.

(51) Int. Cl. H03K 17/082; H03K 19/21

(52) U.S. Cl. CPC H03K 17/0822; H03K 19/21; H03K 2217/0063; H03K 2217/0072

(57) ABSTRACT

The present invention provides a circuitry including a transient detection circuit, a bias buffer, a high-side pre-driver, a low-side pre-driver and a post-driver. The transient detection circuit configured to detect a transient state of an input signal to generate a transient detection result. The bias buffer is configured to generate a low-level reference voltage and a high-level reference voltage according to the transient detection result. The high-side pre-driver is supplied by a supply voltage and the low-level reference voltage, and configured to generate a first driving signal according to the input signal. The low-side pre-driver is supplied by the high-level reference voltage and a ground voltage, and configured to generate a second driving signal according to the input signal. The post-driver is configured to generate an output signal according to the first driving signal and the second driving signal.

### CROSS REFERENCE TO RELATED APPLICATIONS

This application claims the benefit of U.S. Provisional Application No. 63/684,537, filed on Aug. 19, 2024. The content of the application is incorporated herein by reference.

### BACKGROUND

In a conventional overdrive circuitry (e.g., Overdrive IO(Input/Output)), a high-side pre-driver, a low-side pre-driver, and a post-driver are typically included. To account for the voltage tolerance of certain components inside the overdrive circuitry, the overdrive circuitry receives two reference voltages from an external power management integrated circuit (PMIC). These reference voltages include a high-level reference voltage and a low-level reference voltage. The high-side pre-driver operates between a supply voltage and the low-level reference voltage, while the low-side pre-driver operates between the high-level reference voltage and a ground voltage. Furthermore, some components within the post-driver are controlled by the high-level reference voltage and low-level reference voltage.

However, this overdrive circuitry has several drawbacks. First, the supply voltage, high-level reference voltage, and low-level reference voltage may vary differently during operation, leading to an asymmetric condition between the high-side pre-driver and the low-side pre-driver. Second, receiving the high-level reference voltage and low-level reference voltage from an external device requires additional component costs.

### SUMMARY

It is therefore an objective of the present invention to provide an overdrive circuitry, which can internally generate stable high-level and low-level reference voltages, thereby solving the above-mentioned problems.

According to one embodiment of the present invention, a circuitry comprising a transient detection circuit, a bias buffer, a high-side pre-driver, a low-side pre-driver and a post-driver is disclosed. The transient detection circuit configured to detect a transient state of an input signal to generate a transient detection result. The bias buffer is configured to generate a low-level reference voltage and a high-level reference voltage according to the transient detection result. The high-side pre-driver is supplied by a supply voltage and the low-level reference voltage, and configured to generate a first driving signal according to the input signal. The low-side pre-driver is supplied by the high-level reference voltage and a ground voltage, and configured to generate a second driving signal according to the input signal. The post-driver is configured to generate an output signal according to the first driving signal and the second driving signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an overdrive circuitry according to one embodiment of the present invention.

FIG. 2 shows a timing diagram of some signals of FIG. 1 according to one embodiment of the present invention.

FIG. 3 is a diagram illustrating a bias buffer, a high-side pre-driver, a low-side pre-driver and a post-driver of FIG. 1 according to one embodiment of the present invention.

FIG. 4 is a diagram illustrating an overdrive circuitry according to one embodiment of the present invention.

FIG. 5 shows a timing diagram of some signals of FIG. 4 according to one embodiment of the present invention.

FIG. 6 is a diagram illustrating a bias buffer, a high-side pre-driver, a low-side pre-driver and a post-driver of FIG. 4 according to one embodiment of the present invention.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. The terms “couple” and “couples” are intended to mean either an indirect or a direct electrical connection. Thus, if a first device couples to a second device, that connection may be through a direct electrical connection, or through an indirect electrical connection via other devices and connections.

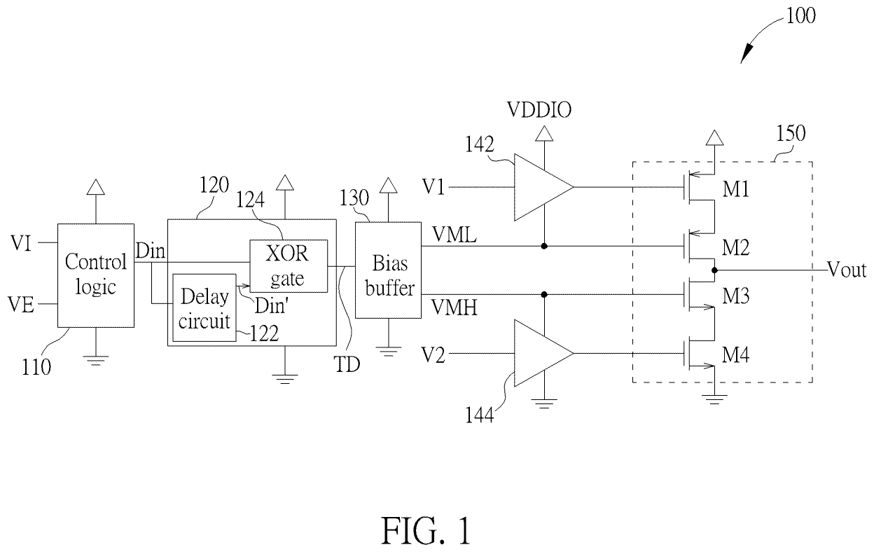

FIG. 1 is a diagram illustrating an overdrive circuitry 100 according to one embodiment of the present invention. As shown in FIG. 1, the overdrive circuitry 100 comprises a control logic 110, a transient detection circuit 120, a bias buffer 130, a high-side pre-driver 142, a low-side pre-driver 144 and a post-driver 150. The transient detection circuit 120 comprises a delay circuit 122 and an exclusive-OR (XOR) gate 124, wherein the delay circuit 122 can be implemented by a delay chain or a Schmitt trigger. The post-driver 150 comprises multiple transistors M1-M4 connected in cascode, wherein the transistors M1 and M2 are implemented by P-type metal-oxide-semiconductor field-effect transistors (P-type MOSFETs), the transistors M3 and M4 are implemented by N-type MOSFETS, and a connection node between the transistors M2 and M3 serves as an output terminal of the overdrive circuitry 100. In addition, in some embodiments, all of the elements of the overdrive circuitry 100 are within a single chip.

The control logic 110 is configured to generate an input signal (digital input signal) Din according to a signal V1 and an enable signal VE. The enable signal VE is used to enable the operation of the control logic 110, that is, when the enable signal VE has an enabling state (e.g., when VE has a logic value “1”), the control logic 110 is enabled so that the input signal Din is generated according to the signal V1, for example, the V1 is input by the control logic as Din. In other embodiments, Din may be a delayed version of V1 or has a predetermined relationship with V1. If the enable signal VE does not have the enabling state (e.g., when VE has a logic value “0”), the control logic 110 is disabled so that the input signal Din is 0 V, and the transient detection circuit 120 is disabled. In one embodiment, without a limitation of the present invention, the control logic 110 can be implemented by a NAND gate with an inverter, and the signal V1 and the input signal Din are clock signals. In some embodiments, the control logic 110 can be removed, such that V1 can always be input into the overdrive circuitry 100 as Din.

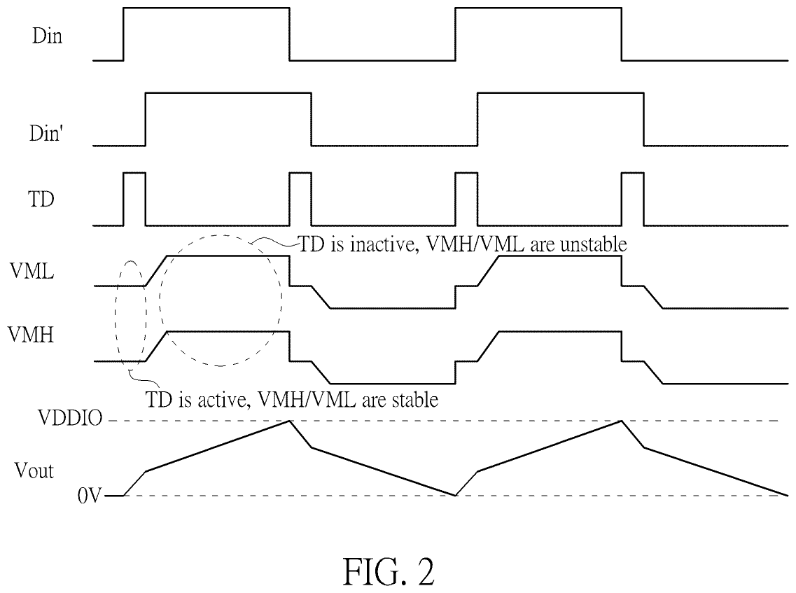

The transient detection circuit 120 is configured to detect a transient state of the input signal Din to generate a transient detection result TD, wherein the transient state of the input signal Din indicates a rising edge or a falling edge of the input signal Din. In the embodiment shown in FIG. 1, the delay circuit 122 delays the input signal Din to generate a delayed input signal Din′, and the XOR gate 124 performs an XOR operation on the input signal Din and the delayed input signal Din′ to generate the transient detection result TD. Referring to FIG. 2 together, when the input signal Din has a rising edge or a falling edge, the transient detection result TD has an enabling state, wherein the period of the enabling state depends on the delay amount of the delay circuit 122. In addition, when both the input signal Din and the delayed input signal Din′ have the same voltage level, the transient detection result TD does not have the enabling state.

The bias buffer 130 is configured to generate a low-level reference voltage VML and a high-level reference voltage VMH, with different driving capabilities based on the transient detection result TD, wherein the high-level reference voltage VMH may be larger or smaller than or equal to the low-level reference voltage VML depends on the design requirement of the overdrive circuitry 100. Specifically, when the transient detection result TD has the enabling state, the bias buffer 130 uses a larger current to generate the low-level reference voltage VML and the high-level reference voltage VMH; and when the transient detection result TD does not have the enabling state, the bias buffer 130 uses a smaller current to generate the low-level reference voltage VML and the high-level reference voltage VMH.

The high-side pre-driver 142 is configured to receive a first signal V1 to generate a first driving signal to the post-driver 150, wherein the first signal V1 can be the input signal Din or any suitable signal derived from the input signal Din. In this embodiment, the high-side pre-driver 142 is supplied by a supply voltage VDDIO and the low-level reference voltage VML, wherein the low-level reference voltage VML is greater than a ground voltage. Specifically, when the first signal V1 has a low voltage level, the high-side pre-driver 142 generates the first driving signal with a lower voltage level (e.g., the low-level reference voltage VML) to enable the transistor M1 of the post-driver 150; and when the first signal V1 has a high voltage level, the high-side pre-driver 142 generates the first driving signal with a higher voltage level (e.g., the supply voltage VDDIO) to disable the transistor M1 of the post-driver 150.

The low-side pre-driver 144 is configured to receive a second signal V2 to generate a second driving signal to the post-driver 150, wherein the second signal V2 can be the input signal Din or any suitable signal derived from the input signal Din. In this embodiment, the low-side pre-driver 144 is supplied by the high-level reference voltage VMH and the ground voltage, wherein the high-level reference voltage VMH is lower than the supply voltage VDDIO. Specifically, when the second signal V2 has a low voltage level, the low-side pre-driver 144 generates the second driving signal with a lower voltage level (e.g., the ground voltage) to disable the transistor M4 of the post-driver 150; and when the second signal V2 has a high voltage level, the low-side pre-driver 144 generates the second driving signal with a higher voltage level (e.g., the high-level reference voltage VMH) to enable the transistor M4 of the post-driver 150.

The post-driver 150 is configured to receive the low-level reference voltage VML, the high-level reference voltage VMH, the first driving signal generated by the high-side pre-driver 142, and the second driving signal generated by the low-side pre-driver 144 to generate an output signal Vout of the overdrive circuitry 100. Specifically, the transistor M2 is always enabled due to the control of the low-level reference voltage VML, the transistor M3 is always enabled due to the control of the high-level reference voltage VMH, and the transistors M1 and M4 are enabled alternately to control the output signal Vout according to the first driving signal and the second driving signal.

Although, in FIG. 1, there is only one bias buffer 130 to provide a same VML to the high-side pre-driver 142 and the post-driver 150, and provide a same VMH to the low-side pre-driver 144 and the post-driver 150, in other embodiments, there may be at least two bias buffers 130 to provide different VMLs (e.g., VML1 and VML2) to the high-side pre-driver 142 and the post-driver 150, and provide different VMHs (e.g., VMH1 and VMH2) to the low-side pre-driver 144 and the post-driver 150, as a result, the influence of the Vout on the high-side pre-driver 142 and the low-side pre-driver 144 is reduced.

In this embodiment, when the input signal Din has a rising edge and the voltage level of the Din transfers from low to high, the output signal Vout will start rising. This rising of the output signal Vout will then pull up the voltage level of the low-level reference voltage VML through the drain-to-gate coupling of transistor M2, and it will also pull up the voltage level of the high-level reference voltage VMH through the drain-to-gate coupling of transistor M3. Similarly, when the input signal Din has a falling edge and the voltage level of the Din transfers from high to low, the output signal Vout will start falling. This falling of the output signal Vout will then pull down the voltage level of the low-level reference voltage VML through the drain-to-gate coupling of transistor M2, it will also pull down the voltage level of the high-level reference voltage VMH through the drain-to-gate coupling of transistor M3. Referring to FIG. 2, when transient detection result TD has the enabling state, the bias buffer 130 can use a larger current to stabilize the low-level reference voltage VML and the high-level reference voltage VMH. This prevents large fluctuations in the low-level reference voltage VML and the high-level reference voltage VMH.

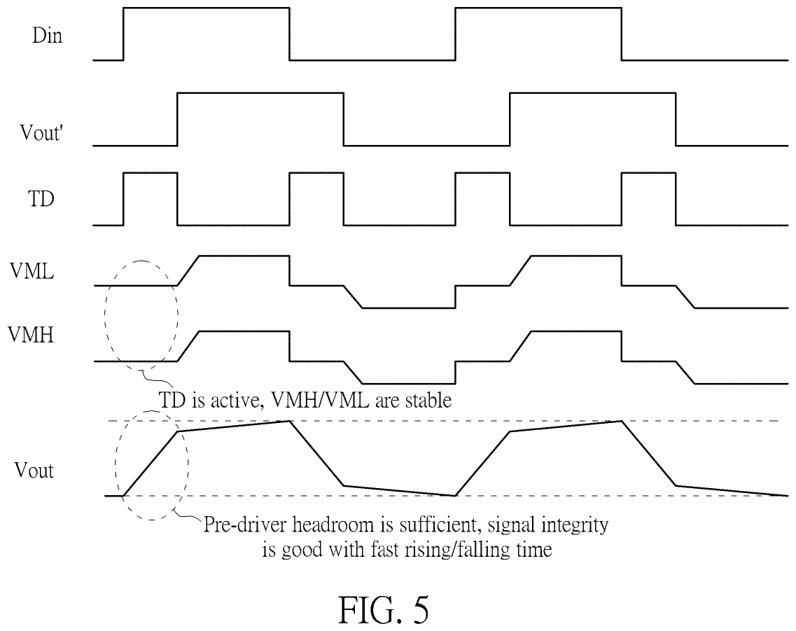

In addition, refers to FIG. 2 and FIG. 5 together, when the delay amount of the delay circuit 122 is longer, the enabling state of the transient detection result TD is also longer, which allows for more effective stabilization of the low-level reference voltage VML and the high-level reference voltage VMH. Accordingly, a designer can control the delay amount of the delay circuit 122 to achieve a balance between signal quality and power consumption.

In addition, considering the voltage tolerance of some components within the overdrive circuitry 100, the high voltage level of the input signal Din, the delayed input signal Din′ and the transient detection result TD may be set as the high-level reference voltage VMH. In addition, the post-driver 150 is supplied by the supply voltage VDDIO and the ground voltage, so the output signal Vout is ranging from VDDIO to ground voltage such as OV. In an embodiment, when the first signal V1 has a low voltage level, the high-side pre-driver 142 generates the first driving signal with a lower voltage level (e.g., the low-level reference voltage VML) to enable the transistor M1 of the post-driver 150, meanwhile, the second signal V2 has a low voltage level, the low-side pre-driver 144 generates the second driving signal with a lower voltage level (e.g., the ground voltage) to disable the transistor M4 of the post-driver 150, the Vout of the post-driver 150 is VDDIO. In another embodiment, when the first signal V1 has a high voltage level, the high-side pre-driver 142 generates the first driving signal with a higher voltage level (e.g., the VDDIO) to disable the transistor M1 of the post-driver 150, meanwhile, the second signal V2 has a high voltage level, the low-side pre-driver 144 generates the second driving signal with a higher voltage level (e.g., the high-level reference voltage VMH) to enable the transistor M4 of the post-driver 150, the Vout of the post-driver 150 is Ground.

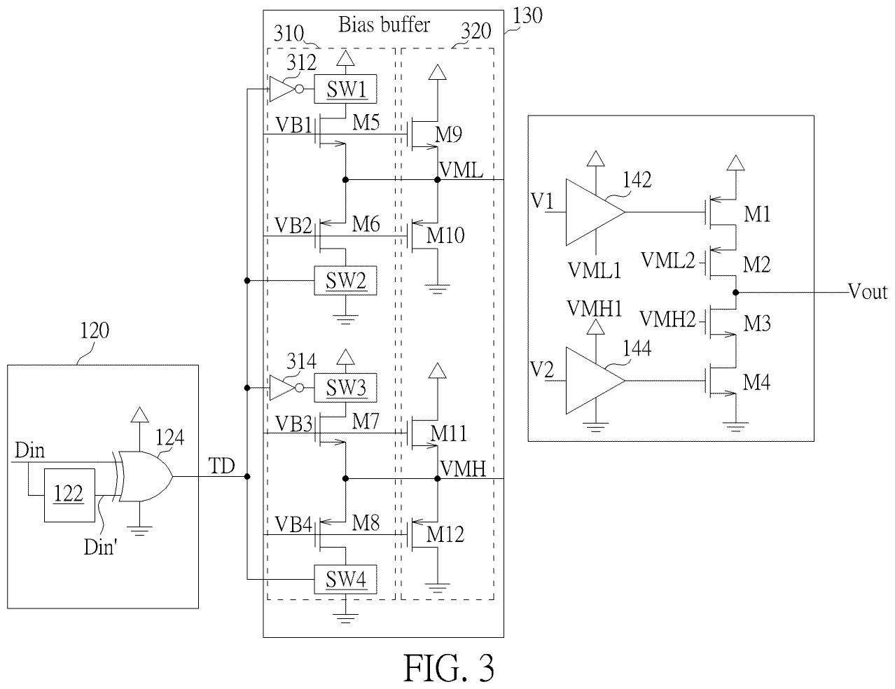

FIG. 3 is a diagram illustrating the bias buffer 130, the high-side pre-driver 142, the low-side pre-driver 144 and the post-driver 150 according to one embodiment of the present invention. As shown in FIG. 3, the bias buffer 130 comprises a boost current circuit 310 and a small current circuit 320. The boost current circuit 310 comprises two inverters 312, 314, four switches SW1-SW4, and four transistors M5-M8, wherein the switch SW1 is coupled between the transistor M5 and a supply voltage, the switch SW2 is coupled between the transistor M6 and the ground voltage, the switch SW3 is coupled between the transistor M7 and the supply voltage, and the switch SW4 is coupled between the transistor M8 and the ground voltage. In addition, the transistors M5-M8 can be always enabled according to the control of the bias voltages VB1-VB4, and the switches SW1-SW4 are controlled according to the transient detection result TD. The small current circuit 320 comprises transistors M9-M12, wherein the transistors M9-M12 can be always enabled according to the control of the bias voltages VB1-VB4. In the embodiment shown in FIG. 3, the small current circuit 320 is always enabled to generate the low-level reference voltage VML (e.g., VML1 or VML2) and the high-level reference voltage VMH (e.g., VMH1 or VMH2) with small current, and the boost current circuit 310 is only enabled when the transient detection result TD has the enabling state to provide larger current to stabilize the low-level reference voltage VML and the high-level reference voltage VMH. In addition, the sizes the transistors M5-M12 can be designed appropriately to generate the low-level reference voltage VML and the high-level reference voltage VMH with desired voltage levels.

It is noted that the circuit structure of the bias buffer 130 shown in FIG. 3 is for illustrative, not a limitation of the present invention. As long as the bias buffer 130 can generate the low-level reference voltage VML and the high-level reference voltage VMH with different driving capabilities based on the transient detection result TD, the bias buffer 130 may have different circuit designs.

In addition, to mitigate the effects on the high-level reference voltage VMH and low-level reference voltage VML caused by drain-to-gate coupling of transistors M2 and M3 during voltage level changes of the output signal Vout, the overdrive circuitry 100 can include at least two bias buffers 130. A first bias buffer 130 generates the low-level reference voltage VML1 and high-level reference voltage VMH1 for the high-side pre-driver 142 and the low-side pre-driver 144, respectively. A second bias buffer 130 generates the low-level reference voltage VML2 and high-level reference voltage VMH2 for the transistors M2 and M3, respectively.

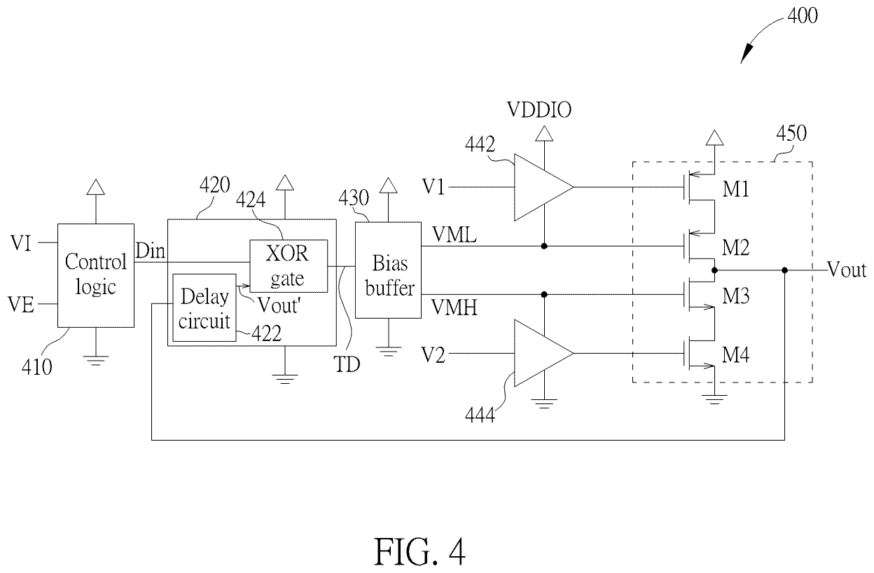

FIG. 4 is a diagram illustrating an overdrive circuitry 400 according to one embodiment of the present invention. As shown in FIG. 4, the overdrive circuitry 400 comprises a control logic 410, a transient detection circuit 420, a bias buffer 430, a high-side pre-driver 442, a low-side pre-driver 444 and a post-driver 450. The transient detection circuit 420 comprises a delay circuit 422 and an XOR gate 424, wherein the delay circuit 422 can be implemented by a delay chain or a Schmitt trigger. The post-driver 450 comprises multiple transistors M1-M4 connected in cascode, wherein the transistors M1 and M2 are implemented by P-type MOSFETs, the transistors M3 and M4 are implemented by N-type MOSFETs, and a connection node between the transistors M2 and M3 serves as an output terminal of the overdrive circuitry 400. In addition, in some embodiments, all of the elements of the overdrive circuitry 400 are within a single chip.

The control logic 410 is configured to generate an input signal (digital input signal) Din according to a signal V1 and an enable signal VE. The enable signal VE is used to enable the operation of the control logic 410, that is, when the enable signal VE has an enabling state, for example, the V1 is input by the control logic as Din. In other embodiments, Din may be a delayed version of V1 or has a predetermined relationship with V1, the control logic 410 is enabled so that the input signal Din is generated according to the signal V1. The way the input signal Din is generated may be similar as that discussed according to FIG. 1. If the enable signal VE does not have the enabling state (e.g., when VE has a logic value “0”), the control logic 410 is disabled so that the input signal Din is OV, and the transient detection circuit 420 is disabled. In one embodiment, without a limitation of the present invention, the control logic 410 can be implemented by a NAND gate with an inverter, and the signal V1 and the input signal Din are clock signals. Similarly, in some embodiments, the control logic 410 can be removed, such that V1 can always be input into the overdrive circuitry 400 as Din.

The transient detection circuit 420 is configured to detect a transient state of the input signal Din to generate a transient detection result TD, wherein the transient state of the input signal Din indicates a rising edge or a falling edge of the input signal Din. In the embodiment shown in FIG. 4, the delay circuit 422 delays an output signal Vout of the overdrive circuitry 400 to generate a delayed output signal Vout′, and the XOR gate 424 performs an XOR operation on the input signal Din and the delayed output signal Vout′ to generate the transient detection result TD. Referring to FIG. 5 together, when the input signal Din has a rising edge or a falling edge, the transient detection result TD has an enabling state, wherein the period of the enabling state depends on the delay amount of the delay circuit 422. In addition, when both the input signal Din and the delayed output signal Vout′ have the same voltage level, the transient detection result TD does not have the enabling state. In the example of FIG. 4, Vout is feedback directly to the Delay circuit 422, however in an alternative embodiment, a divisional version or multiple version of Vout may be feedback instead of the Vout itself. Further, since Vout already has a delay compared to the input signal Din, in some embodiment, when using Vout as a feedback signal, delay circuit 422 may be removed, and the Vout can be input to XOR gate directly.

The bias buffer 430 is configured to generate a low-level reference voltage VML and a high-level reference voltage VMH, with different driving capabilities based on the transient detection result TD, wherein the high-level reference voltage VMH may be larger, or smaller than or equal to the low-level reference voltage VML depends on the design requirement of the overdrive circuitry 400. Specifically, when the transient detection result TD has the enabling state, the bias buffer 430 uses a larger current to generate the low-level reference voltage VML and the high-level reference voltage VMH; and when the transient detection result TD does not have the enabling state, the bias buffer 430 uses a smaller current to generate the low-level reference voltage VML and the high-level reference voltage VMH.

The high-side pre-driver 442 is configured to receive a first signal V1 to generate a first driving signal to the post-driver 450, wherein the first signal V1 can be the input signal Din or any suitable signal derived from the input signal Din. In this embodiment, the high-side pre-driver 442 is supplied by a supply voltage VDDIO and the low-level reference voltage VML, wherein the low-level reference voltage VML is greater than a ground voltage. Specifically, when the first signal V1 has a low voltage level, the high-side pre-driver 442 generates the first driving signal with a lower voltage level (e.g., the low-level reference voltage VML) to enable the transistor M1 of the post-driver 450; and when the first signal V1 has a high voltage level, the high-side pre-driver 442 generates the first driving signal with a higher voltage level (e.g., the supply voltage VDDIO) to disable the transistor M1 of the post-driver 450.

The low-side pre-driver 444 is configured to receive a second signal V2 to generate a second driving signal to the post-driver 450, wherein the second signal V2 can be the input signal Din or any suitable signal derived from the input signal Din. In this embodiment, the low-side pre-driver 444 is supplied by the high-level reference voltage VMH and the ground voltage, wherein the high-level reference voltage VMH is lower than the supply voltage VDDIO. Specifically, when the second signal V2 has a low voltage level, the low-side pre-driver 444 generates the second driving signal with a lower voltage level (e.g., the ground voltage) to disable the transistor M4 of the post-driver 450; and when the second signal V2 has a high voltage level, the low-side pre-driver 444 generates the second driving signal with a higher voltage level (e.g., the high-level reference voltage VMH) to enable the transistor M4 of the post-driver 450.

The post-driver 450 is configured to receive the low-level reference voltage VML, the high-level reference voltage VMH, the first driving signal generated by the high-side pre-driver 442, and the second driving signal generated by the low-side pre-driver 444 to generate the output signal Vout of the overdrive circuitry 400. Specifically, the transistor M2 is always enabled due to the control of the low-level reference voltage VML, the transistor M3 is always enabled due to the control of the high-level reference voltage VMH, and the transistors M1 and M4 are enabled alternately to control the output signal Vout according to the first driving signal and the second driving signal.

Although, in FIG. 4, there is only one bias buffer 430 to provide a same VML to the high-side pre-driver 442 and the post-driver 450, and provide a same VMH to the low-side pre-driver 444 and the post-driver 450, in other embodiments, there may be at least two bias buffers 430 to provide different VMLs (e.g., VML1 and VML2) to the high-side pre-driver 442 and the post-driver 450, and provide different VMHs (e.g., VMH1 and VMH2) to the low-side pre-driver 444 and the post-driver 450, as a result, the influence of the Vout on the high-side pre-driver 442 and the low-side pre-driver 444 is reduced.

In this embodiment, when the input signal Din has a rising edge and the voltage level of the Din transfers from low to high, the output signal Vout will start rising. This rising of the output signal Vout will then pull up the voltage level of the low-level reference voltage VML through the drain-to-gate coupling of transistor M2, and it will also pull up the voltage level of the high-level reference voltage VMH through the drain-to-gate coupling of transistor M3. Similarly, when the input signal Din has a falling edge and the voltage level of the Din transfers from high to low, the output signal Vout will start falling. This falling of the output signal Vout will then pull down the voltage level of the low-level reference voltage VML through the drain-to-gate coupling of transistor M2, it will also pull down the voltage level of the high-level reference voltage VMH through the drain-to-gate coupling of transistor M3. Referring to FIG. 5, when transient detection result TD has the enabling state, the bias buffer 430 can use a larger current to stabilize the low-level reference voltage VML and the high-level reference voltage VMH. This prevents large fluctuations in the low-level reference voltage VML and the high-level reference voltage VMH.

As shown in FIG. 5, in the embodiment of FIG. 4, since the output signal Vout itself has a delay compared to the input signal Din, the delayed output signal Vout′ generated by the delay circuit 422 will have a greater delay relative to the input signal Din, causing the transient detection result TD generated by the transient detection circuit 420 have longer enabling state. Therefore, compared with the embodiment shown in FIG. 1, because the enabling state of the transient detection result TD generated by the transient detection circuit 420 is longer, the low-level reference voltage VML and the high-level reference voltage VMH have more stabilization time, so that the headroom of the high-side pre-driver 442 and low-side pre-driver 444 is sufficient, and the signal integrity of the output signal Vout becomes better with fast rising time and falling time.

In addition, considering the voltage tolerance of some components within the overdrive circuitry 400, the high voltage level of the input signal Din, the delayed output signal Vout′ and the transient detection result TD may be set as the high-level reference voltage VMH. In addition, the post-driver 450 is supplied by the supply voltage VDDIO and the ground voltage, so the output signal Vout is ranging from VDDIO to ground voltage such as OV.

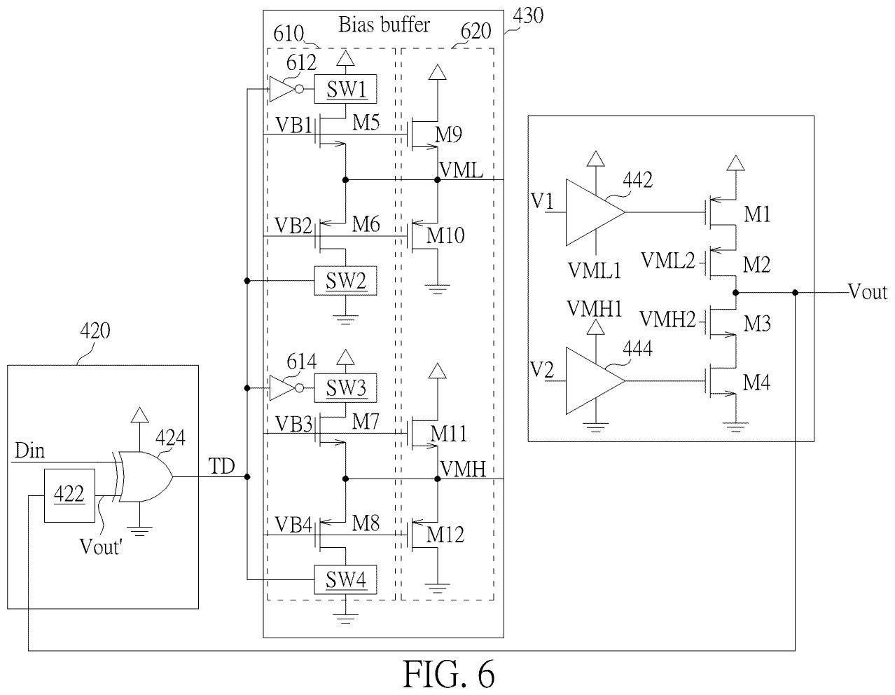

FIG. 6 is a diagram illustrating the bias buffer 430, the high-side pre-driver 442, the low-side pre-driver 444 and the post-driver 450 according to one embodiment of the present invention. As shown in FIG. 6, the bias buffer 430 comprises a boost current circuit 610 and a small current circuit 620. The boost current circuit 610 comprises two inverters 612, 614, four switches SW1-SW4, and four transistors M5-M8, wherein the switch SW1 is coupled between the transistor M5 and a supply voltage, the switch SW2 is coupled between the transistor M6 and the ground voltage, the switch SW3 is coupled between the transistor M7 and the supply voltage, and the switch SW4 is coupled between the transistor M8 and the ground voltage. In addition, the transistors M5-M8 can be always enabled according to the control of the bias voltages VB1-VB4, and the switches SW1-SW4 are controlled according to the transient detection result TD. The small current circuit 620 comprises transistors M9-M12, wherein the transistors M9-M12 can be always enabled according to the control of the bias voltages VB1-VB4. In the embodiment shown in FIG. 6, the small current circuit 620 is always enabled to generate the low-level reference voltage VML and the high-level reference voltage VMH with small current, and the boost current circuit 610 is only enabled when the transient detection result TD has the enabling state to provide larger current to stabilize the low-level reference voltage VML (e.g., VML1 or VML2) and the high-level reference voltage VMH (e.g., VMH1 or VMH2). In addition, the sizes the transistors M5-M12 can be designed appropriately to generate the low-level reference voltage VML and the high-level reference voltage VMH with desired voltage levels.

It is noted that the circuit structure of the bias buffer 430 shown in FIG. 6 is for illustrative, not a limitation of the present invention. As long as the bias buffer 430 can generate the low-level reference voltage VML and the high-level reference voltage VMH with different driving capabilities based on the transient detection result TD, the bias buffer 430 may have different circuit designs.

In addition, to mitigate the effects on the high-level reference voltage VMH and low-level reference voltage VML caused by drain-to-gate coupling of transistors M2 and M3 during voltage level changes of the output signal Vout, the overdrive circuitry 400 can include at least two bias buffers 430. A first bias buffer 430 generates the low-level reference voltage VML1 and high-level reference voltage VMH1 for the high-side pre-driver 442 and the low-side pre-driver 444, respectively. A second bias buffer 430 generates the low-level reference voltage VML2 and high-level reference voltage VMH2 for the transistors M2 and M3, respectively.

Briefly summarized, in the circuitry of the present invention, by using the transient detection circuit to detect a transient state of an input signal to generate a transient detection result, for determining driving capabilities of the bias buffer to generate a low-level reference voltage and a high-level reference voltage, for use by high-side pre-driver, low-side pre-driver and post driver, the low-level reference voltage and the high-level reference voltage can be more stable, and the output signal will have better signal integrity. In addition, because the low-level reference voltage and the high-level reference voltage are generated internally by the chip, rather than from an external PMIC, manufacturing costs can be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A circuitry, comprising:
a transient detection circuit, configured to detect a transient state of an input signal to generate a transient detection result;
a bias buffer, configured to generate a low-level reference voltage and a high-level reference voltage according to the transient detection result;
a high-side pre-driver, supplied by a supply voltage and the low-level reference voltage, and configured to generate a first driving signal according to the input signal;
a low-side pre-driver, supplied by the high-level reference voltage and a ground voltage, and configured to generate a second driving signal according to the input signal; and
a post-driver, configured to generate an output signal according to the first driving signal and the second driving signal.

2. The circuitry of claim 1, wherein the transient detection circuit comprises:
a delay circuit, configured to delay the input signal to generate a delayed input signal; and
an exclusive-OR (XOR) gate, configured to perform an XOR operation on the input signal and the delayed input signal to generate the transient detection result.

3. The circuitry of claim 2, wherein the delay circuit is a delay chain or a Schmitt trigger.

4. The circuitry of claim 1, wherein the transient detection circuit comprises:
a delay circuit, configured to delay a feedback signal obtained from the output signal to generate a delayed output signal; and
an XOR gate, configured to perform an XOR operation on the input signal and the delayed output signal to generate the transient detection result.

5. The circuitry of claim 4, wherein the feedback signal is the output signal, a divisional version of the output signal, or a multiple version of the output signal.

6. The circuitry of claim 4, wherein the delay circuit is a delay chain or a Schmitt trigger.

7. The circuitry of claim 1, wherein the transient detection circuit comprises:
an XOR gate, configured to perform an XOR operation on the input signal and a feedback signal obtained from the output signal to generate the transient detection result.

8. The circuitry of claim 7, wherein the feedback signal is the output signal, a divisional version of the output signal, or a multiple version of the output signal.

9. The circuitry of claim 1, wherein the bias buffer is configured to generate the low-level reference voltage and the high-level reference voltage, with different driving capabilities according to the transient detection result.

10. The circuitry of claim 9, wherein when the transient detection result has an enabling state, the bias buffer uses a first current to generate the low-level reference voltage and the high-level reference voltage; and when the transient detection result does not have the enabling state, the bias buffer uses a second current to generate the low-level reference voltage and the high-level reference voltage, wherein the first current is larger than the second current.

11. The circuitry of claim 1, wherein the post-driver is configured to generate the output signal according to the first driving signal, the second driving signal, the low-level reference voltage and the high-level reference voltage.

12. The circuitry of claim 1, wherein the high-level reference voltage is larger than the low-level reference voltage.

13. The circuitry of claim 1, wherein the high-level reference voltage is equal to the low-level reference voltage.

14. The circuitry of claim 1, the bias buffer is a first bias buffer, the low-level reference voltage is a first low-level reference voltage, the high-level reference voltage is a first high-level reference voltage, the circuitry further comprising:
a second bias buffer, configured to generate a second low-level reference voltage and a second high-level reference voltage according to the transient detection result;
wherein the post-driver is configured to generate the output signal according to the first driving signal, the second driving signal, the second low-level reference voltage and the second high-level reference voltage.

15. The circuitry of claim 1, further comprising:
a control logic, configured to generate the input signal according to an original signal and an enable signal, wherein when the enable signal has an enabling state, the control logic is enabled and the input signal is generated according to the original signal.

16. The circuitry of claim 11, wherein the post-driver comprises:
a first P-type metal-oxide-semiconductor field-effect transistor, having a source terminal coupled to the supply voltage, a gate terminal coupled to an output terminal of the high-side pre-driver for receiving the first driving signal, and a drain terminal;
a second P-type metal-oxide-semiconductor field-effect transistor, having a source terminal coupled to the drain terminal of the first P-type metal-oxide-semiconductor field-effect transistor, a gate terminal coupled to an output of the bias buffer for receiving the low-level reference voltage, and a drain terminal for outputting the output signal;
a first N-type metal-oxide-semiconductor field-effect transistor, having a drain terminal coupled to the drain terminal of the second P-type metal-oxide-semiconductor field-effect transistor, a gate terminal coupled to an output of the bias buffer for receiving the high-level reference voltage, and a source terminal; and
a second N-type metal-oxide-semiconductor field-effect transistor, having a drain terminal coupled to the source terminal of the first N-type metal-oxide-semiconductor field-effect transistor, a gate terminal coupled to an output of the low-side pre-driver for receiving the second driving signal, and a source terminal coupled to the ground voltage.

17. The circuitry of claim 14, wherein the post-driver comprises:
a first P-type metal-oxide-semiconductor field-effect transistor, having a source terminal coupled to the supply voltage, a gate terminal coupled to an output terminal of the high-side pre-driver for receiving the first driving signal, and a drain terminal;
a second P-type metal-oxide-semiconductor field-effect transistor, having a source terminal coupled to the drain terminal of the first P-type metal-oxide-semiconductor field-effect transistor, a gate terminal coupled to an output of the second bias buffer for receiving the second low-level reference voltage, and a drain terminal for outputting the output signal;
a first N-type metal-oxide-semiconductor field-effect transistor, having a drain terminal coupled to the drain terminal of the second P-type metal-oxide-semiconductor field-effect transistor, a gate terminal coupled to an output of the second bias buffer for receiving the second high-level reference voltage, and a source terminal; and
a second N-type metal-oxide-semiconductor field-effect transistor, having a drain terminal coupled to the source terminal of the first N-type metal-oxide-semiconductor field-effect transistor, a gate terminal coupled to an output of the low-side pre-driver for receiving the second driving signal, and a source terminal coupled to the ground voltage.
